(19) United States
(12) Patent Application Publication
(10) Pub. No.: US 2019/0112469 A1
(43) Pub. Date: Apr. 18, 2019

(54) SEALANT COMPOSITION FOR ORGANIC SOLAR CELL, SEALANT FOR ORGANIC SOLAR CELL, ELECTRODE FOR ORGANIC SOLAR CELL AND ORGANIC SOLAR CELL

(71) Applicant: ZEON CORPORATION, Chiyoda-ku Tokyo (JP)

(72) Inventors: Akihiko YOSHIWARA, Chiyoda-ku, Tokyo (JP); Yuki HAYASHI, Chiyoda-ku, Tokyo (JP)

(73) Assignee: ZEON CORPORATION, Chiyoda-ku Tokyo (JP)

(21) Appl. No.: 16/088,970

(22) PCT Filed: Mar. 21, 2017
(86) PCT No.: PCT/JP2017/011244

§ 371 Date: Sep. 27, 2018

(30) Foreign Application Priority Data
Mar. 30, 2016 (JP) 2016-069244

(51) Int. Cl. C08L 63/04; C08K 5/1539; C08K 5/07; C08K 5/31; C08K 3/36; C08K 9/06; H01G 9/20

(52) U.S. Cl. CPC C08L 63/04; C08K 5/1539; C08K 5/07; C08K 5/31; C08K 3/36; H01L 51/448; H01G 9/2095; H01G 9/2022; H01G 9/2077; C08L 2203/204; C08K 9/06

(57) ABSTRACT

The disclosure relates to a sealant composition for an organic solar cell, comprising (A) a hydrogenated epoxy resin, (B) a photobase generator, and (C) an anionically curable compound other than the component (A). The disclosure also relates to a sealant for an organic solar cell, which is a cured product of the sealant composition. The disclosure further relates to an electrode for an organic solar cell, comprising a substrate, a current collecting wire on the substrate, and a sealant covering the current collecting wire, wherein the current collecting wire is a photocured product, and the sealant is a photocured product of the sealant composition. The disclosure further relates to an organic solar cell prepared by using the sealant composition.

### TECHNICAL FIELD

The disclosure relates to a sealant composition for an organic solar cell, a sealant for an organic solar cell, an electrode for an organic solar cell and an organic solar cell.

### BACKGROUND

In organic solar cells such as dye-sensitized solar cells and perovskite solar cells, sealants are used for the protection of current collecting wires or the encapsulation of electrolyte solutions.

Dye-sensitized solar cell modules include various modules. One example of the modules is a general current collecting wiring module (also referred to as a grid wiring module) as shown in FIG. 1. This current collecting wiring module 1 has electrolyte layer 7 within a space surrounded by photoelectrode substrate 2 (comprising conductive film 3), counter electrode substrate 4 (comprising catalyst layer 5), and sealant 6. Further, current collecting wire 8 is present in the electrolyte layer 7 and is covered with sealant 9 for protection. Also, porous semiconductor fine particle layer 10 is formed on the conductive film 3.

Such a sealant is required to have excellent adhesiveness to an adherend such as a current collecting wire (metal wire) or a substrate. Also, the sealant is required to have high reliability, i.e., low reactivity with an electrolyte. High reactivity facilitates swelling or deteriorating the sealant due to an electrolyte solution, leading to reduction in photoelectric conversion efficiency.

For example, PTL 1 discloses an electrode for dye-sensitized solar cells. In Examples thereof, a silicone resin curable by heating is used as an encapsulation material for current collecting wire protection. However, a total of three heating steps are necessary involving one for the preparation of a current collecting wire, one for the preparation of a protective layer and one for the preparation of a TiO₂ layer, because the silicone resin is a resin curable by heating. Hence, this approach presents many problems such as time-consuming curing of these layers, low productivity, and, particularly, in the case of using a flexible base plate, the deformation of the base plate by cure shrinkage which might deteriorate the bonding accuracy of a module, and insufficient electrolyte solution resistance resulting in the corrosion of a current collecting wire and reduction in photoelectric conversion efficiency.

For example, PTL 2 discloses an encapsulant composition for photoelectric conversion elements, comprising (A) a hydrogenated novolac-type epoxy resin, (B) an epoxy resin that is in a liquid state at ordinary temperature, selected from the group consisting of a hydrogenated epoxy resin and an aromatic epoxy resin having no hydroxy group in the molecule, and (C) a cationic initiator, wherein the encapsulant composition contains 20 to 80 parts by mass of the component (A) in 100 parts by mass in total of the component (A) and the component (B). In such a UV cationic polymerization system, corrosion might be caused by a cationic polymerization catalyst. PTL 2 also discloses an epoxy resin having a hydroxy group and a radical polymerizable compound as optional components. However, the presence of water, an OH group, or the like in the cationic curing system facilitates poor curing. For example, a resin for use in a current collecting wire of Ag (Ag paste) or the like is often an epoxy resin or the like, and an epoxy group-derived OH group causes problems such as curing inhibition. Furthermore, if a protective layer for an electrode or the like is prepared using a resin of the UV radical polymerization system, adhesiveness might be insufficient.

### CITATION LIST

### Patent Literature

PTL 1: JP2008-251421A

PTL 2: JP2013-089578A

### SUMMARY

### Technical Problem

Accordingly, an object of the disclosure is to provide a sealant composition for an organic solar cell capable of forming a sealant that exerts sufficient photocurability, is excellent in adhesiveness to a current collecting wire, and has highly reliable sealing performance. Another object of the disclosure is to provide a sealant for an organic solar cell, which is excellent in adhesiveness to a current collecting wire and has highly reliable sealing performance. A further object of the disclosure is to provide an electrode for an organic solar cell, which is excellent in the adhesiveness between a sealant and a current collecting wire and is highly reliable. A further object of the disclosure is to provide an organic solar cell that is excellent in the adhesiveness between a sealant and a current collecting wire, reduces electrode deformation, has high bonding accuracy of a module, and is highly reliable.

### Solution to Problem

The sealant composition for an organic solar cell according to the disclosure is a sealant composition for an organic solar cell, comprising:

(A) a hydrogenated epoxy resin;

(B) a photobase generator; and

(C) an anionically curable compound other than the component (A).

The composition thus configured can form a sealant that exerts sufficient photocurability, is excellent in adhesiveness to a current collecting wire, and has highly reliable sealing performance.

For the sealant composition for an organic solar cell according to the disclosure, it is preferred that the component (A) should be a hydrogenated novolac-type epoxy resin and/or a hydrogenated bisphenol-type epoxy resin.

For the sealant composition for an organic solar cell according to the disclosure, it is preferred that the component (C) should comprise a cyclic epoxy resin.

For the sealant composition for an organic solar cell according to the disclosure, it is preferred that the sealant composition should comprise 20 to 80 parts by mass of the component (A) per 100 parts by mass in total of the component (A) and the component (C). This is effective for improving screen printability.

It is preferred that the sealant composition for an organic solar cell according to the disclosure should further comprise (D) an acid anhydride and/or (E) a radical photoinitiator. This is effective for being able to accelerate the curing of the sealant composition for an organic solar cell by heating. Examples thereof include heating during the preparation of a TiO₂ layer.

It is preferred that the sealant composition for an organic solar cell according to the disclosure should further comprise (F) a filler. This is effective for enhancing a mechanical property.

The sealant for an organic solar cell according to the disclosure is preferably a cured product of any of the sealant compositions for an organic solar cell described above. This sealant is excellent in adhesiveness to a current collecting wire and has highly reliable sealing performance.

The sealant for an organic solar cell according to the disclosure is preferably prepared by curing any of the sealant compositions for an organic solar cell described above by light irradiation, followed by further curing by heating. The curing of the sealant is accelerated by the heating, and the resulting sealant is excellent in adhesiveness to a current collecting wire and has highly reliable sealing performance.

The electrode for an organic solar cell according to the disclosure is an electrode for an organic solar cell, comprising:

a substrate;

a current collecting wire on the substrate; and

a sealant covering the current collecting wire, wherein

the current collecting wire is a photocured product, and

the sealant is a photocured product of any of the sealant compositions for an organic solar cell described above.

The electrode comprising such a photocured product is excellent in the adhesiveness between a sealant and a current collecting wire and has high reliability.

The electrode for an organic solar cell according to the disclosure can also be suitably used when the substrate is a flexible substrate.

For the electrode for an organic solar cell according to the disclosure, it is preferred that the electrode for an organic solar cell should be a photoelectrode, wherein the photoelectrode comprises a porous semiconductor fine particle layer and

is prepared by photocuring the current collecting wire and the sealant, then coating the substrate with a material for the porous semiconductor fine particle layer, and heating the sealant and the material for the porous semiconductor fine particle layer to form the porous semiconductor fine particle layer.

The curing of the sealant is accelerated by the heating in forming the porous semiconductor fine particle layer, and the resulting electrode is excellent in the adhesiveness between a sealant and a current collecting wire and has high reliability.

For the electrode for an organic solar cell according to the disclosure, it is preferred that a temperature of the heating should be 150° C. or lower. This is effective for achieving both reduction in wrinkles, deflection, etc., particularly, in a thin resin film having low heat resistance, such as an organic resin, and improvement in close adherence and reliability owing to improvement in the degree of curing of Ag paste as a current collecting wire, or an encapsulation material by heating.

The organic solar cell according to the disclosure is preferably an organic solar cell prepared by using any of the sealant compositions for an organic solar cell described above. This organic solar cell is excellent in the adhesiveness between a sealant and a current collecting wire and has high reliability.

The organic solar cell according to the disclosure is preferably an organic solar cell comprising any of the electrodes for an organic solar cell described above. This organic solar cell is excellent in the adhesiveness between a sealant and a current collecting wire and has high reliability.

### Advantageous Effect

The disclosure can provide a sealant composition for an organic solar cell capable of forming a sealant that exerts sufficient photocurability, is excellent in adhesiveness to a current collecting wire, and has highly reliable sealing performance. The disclosure can provide a sealant for an organic solar cell, which is excellent in adhesiveness to a current collecting wire and has highly reliable sealing performance. The disclosure can provide an electrode for an organic solar cell, which is excellent in the adhesiveness between a sealant and a current collecting wire and is highly reliable. The disclosure can provide an organic solar cell that is excellent in the adhesiveness between a sealant and a current collecting wire and is highly reliable.

### BRIEF DESCRIPTION OF THE DRAWINGS

FIG. 1 is one example of a schematic cross-sectional view of a general current collecting wiring module.

### DETAILED DESCRIPTION

Hereinafter, embodiments of the disclosure will be described. The description below is intended to illustrate the disclosure and does not limit the disclosure by any means.

In the present specification, a numeric range intends to include a lower limit value and an upper limit value of the range unless otherwise specified. For example, 20 to 80 parts by mass intend to include the lower limit value of 20 parts by mass and the upper limit value of 80 parts by mass and mean 20 parts by mass or more and 80 parts by mass or less.

(Sealant Composition for Organic Solar Cell)

The sealant composition for an organic solar cell according to the disclosure is a sealant composition for an organic solar cell (hereinafter, also simply referred to as a “sealant composition”) comprising:

(A) a hydrogenated epoxy resin;

(B) a photobase generator; and

(C) an anionically curable compound other than the component (A).

The sealant composition thus configured can form a sealant that exerts sufficient photocurability, is excellent in adhesiveness to a current collecting wire, and has highly reliable sealing performance.

<Component (A)>

The component (A) is a hydrogenated epoxy resin. The component (A) is curable by a base generated by the component (B) mentioned later. Also, the component (A) is curable by heating.

A hydrogenated novolac-type epoxy resin and/or a hydrogenated bisphenol resin known in the art can be used as the component (A). Examples of the component (A) include hydrogenated phenol novolac-type epoxy resins, hydrogenated cresol novolac-type epoxy resins, hydrogenated novolac-type epoxy resins of bisphenol A, and hydrogenated bisphenol resins.

The method for preparing the component (A) is not particularly limited, and a method known in the art can be used. Examples thereof include a method of obtaining the component (A) through the hydrogenation reaction of an aromatic epoxy resin in the presence of a rhodium- or ruthenium-supported graphite catalyst without a solvent or with an organic ether solvent such as tetrahydrofuran or dioxane.

A commercially available product may be used as the component (A). Examples of the commercially available product include product names jER® YX-8000 and YL-7717 manufactured by Mitsubishi Chemical Corporation.

Examples of the hydrogenated bisphenol resin include hydrogenated bisphenol A-type epoxy resins, diglycidyl ether of an alkylene oxide adduct of hydrogenated bisphenol A, hydrogenated bisphenol F-type epoxy resins, and diglycidyl ether of an alkylene oxide adduct of hydrogenated bisphenol F. Specific examples thereof include YX8034 (bisphenol A-type epoxy resin) manufactured by Japan Epoxy Resin Co., Ltd., UXA7015 manufactured by DIC Corp., ST3000 manufactured by Tohto Kasei Co., Ltd., Rikaresin HBE-100 manufactured by Nippon Rika Industries Corp., and ST-3000 and ST4000D manufactured by Nippon Steel & Sumikin Chemical Co., Ltd.

The component (A) may be used singly or in combinations of two or more thereof.

<Component (B)>

The component (B) is a photobase generator. Specifically, the component (B) is a compound that generates a base by irradiation with active energy line such as visible light or ultraviolet ray.

Examples of the base that is generated by the irradiation of the component (B) with active energy line include amine compounds, imidazole compounds, amidine compounds, guanidine compounds, phosphine compounds, and boron compounds.

The component (B) can be any compound capable of generating a base by irradiation with active energy line and is not particularly limited. A photobase generator known in the art can be used. Examples of the component (B) can include: imidazole derivatives such as N-(2-nitrobenzyloxycarbonyl)imidazole, N-(3-nitrobenzyloxycarbonyl)imidazole, N-(4-nitrobenzyloxycarbonyl)imidazole, N-(4-chloro-2-nitrobenzyloxycarbonyl)imidazole, N-(5-methyl-2-nitrobenzyloxycarbonyl)imidazole, and N-(4,5-dimethyl-2-nitrobenzyloxycarbonyl)imidazole; and N-(2-methyl-2-phenylpropionyloxy)-N-cyclohexylamine.

In addition, specific examples of the component (B) can include: nonionic photobase generators such as 9-anthrylmethyl N,N-diethylcarbamate, (E)-1-[3-(2-hydroxyphenyl)-2-propenoyl]piperidine, 1-(anthraquinon-2-yl)ethyl imidazole carboxylate, and 2-nitrophenylmethyl 4-methacryloyloxypiperidine-1-carboxylate; and ionic photobase generators such as 1,2-diisopropyl-3-[bis(dimethylamino)methylene]guanidium 2-(3-benzoylphenyl)propionate and 1,2-dicyclohexyl-4,4,5,5-tetramethylbiguanidium n-butyltriphenylborate. These components (B) can be appropriately selected according to solubility with the components (A) and (C), etc. contained, and the wavelength of the active energy line used and may be used in combination with a sensitizer.

The method for preparing the component (B) is not particularly limited, and a method known in the art can be used. Examples thereof include a synthesis method of reacting a nitrobenzyl alcohol derivative as a starting material with carbonyldiimidazole. Also, the curing agent can be prepared in accordance with, for example, a method described in Nishikubo, T. et al, Polym. J., 26 (7), 864 (1994).

A commercially available product may be used as the component (B). Examples of the commercially available product include WPBG series such as product names WPBG-018, 027, 140, 165, 266, and 300 manufactured by Wako Pure Chemical Industries, Ltd.

The amount of the component (B) contained is not particularly limited and can be appropriately adjusted. The amount is, for example, usually 0.01 parts by mass or more, preferably 0.1 parts by mass or more, more preferably 1 part by mass or more and is usually 20 parts by mass or less, preferably 10 parts by mass or less, more preferably 5 parts by mass or less, particularly preferably 3 parts by mass or less, per 100 parts by mass in total of the component (A) and the component (C).

The component (B) may be used singly or in combinations of two or more thereof.

<Component (C)>

The component (C) is an anionically curable compound. However, among anionically polymerizable compounds, the hydrogenated epoxy resin (A) is treated as the component (A) and excluded from the component (C). The component (C) is curable by a base generated by the component (B). Also, the component (C) is curable by heating.

For example, a compound that causes ring-opening reaction, such as an epoxy resin, other than the component (A), known in the art, an oxetane compound, or an episulfide compound can be used as the component (C). Examples of the epoxy resin, other than the component (A), known in the art include: bisphenol resins; cyclic epoxy resins; and aromatic epoxy resins and aliphatic epoxy resins containing no hydroxyl group or containing a hydroxyl group.

Examples of the cyclic epoxy resin include 3,4-epoxycyclohexylmethyl 3′,4′-epoxycyclohexanecarboxylate, ε-caprolactone oligomers both terminally ester-bonded with 3,4-epoxycyclohexylmethanol and 3,4-epoxycyclohexanecarboxylic acid, respectively, bis(3,4-epoxycyclohexylmethyl)adipate, epoxylated products of ester of tetrahydrophthalic acid and tetrahydrobenzyl alcohol and ε-caprolactone addition products thereof, and epoxylated butanetetracarboxylic acid tetrakis-3-cyclohexenyl methyl ester and ε-caprolactone addition products thereof.

Examples of the aromatic epoxy resin containing no hydroxyl group include: reaction products of polyhydric phenol having at least one aromatic nucleus, and epichlorohydrin; and reaction products of an alkylene oxide adduct of polyhydric phenol having at least one aromatic nucleus, and epichlorohydrin.

When the polyhydric phenol having at least one aromatic nucleus is bisphenol, specific examples of the epoxy resin include aromatic bisphenol A-type epoxy resins, diglycidyl ether of an alkylene oxide adduct of aromatic bisphenol A, aromatic bisphenol F-type epoxy resins, and diglycidyl ether of an alkylene oxide adduct of aromatic bisphenol F.

An aromatic bisphenol epoxy resin purified by distillation in high vacuum or the like is preferably used. Examples of commercially available products of the distilled aromatic bisphenol A-type epoxy resin and aromatic bisphenol F-type epoxy resin include: product names EPICLON® EXA-850CRP, EXA-83CRP, EXA-830LVP, and EXA-835LV manufactured by DIC Corp.; and product names YDF-8170C and YD-8125 manufactured by Nippon Steel & Sumikin Chemical Co., Ltd.

When the polyhydric phenol having at least one aromatic nucleus is resorcinol, examples of the epoxy resin include resorcinol diglycidyl ether. Examples of a commercially available product of the resorcinol diglycidyl ether containing no hydroxyl group include product name EX-201 manufactured by Nagase ChemteX Corp.

Examples of a commercially available product of the aromatic epoxy resin containing a hydroxyl group include: product names jER®807, 828US, and 1003 manufactured by Mitsubishi Chemical Corporation; and product name EPICLON® HP-820 manufactured by DIC Corp.

The aliphatic epoxy resin is an aliphatic polyhydric alcohol, or polyglycidyl ether of an alkylene oxide addition product thereof or polyglycidyl ether of an alkylene oxide adduct thereof. Specific examples thereof include 1,4-butanediol diglycidyl ether, 1,6-hexanediol diglycidyl ether, glycerin triglycidyl ether, trimethylolpropane triglycidyl ether, polyethylene glycol diglycidyl ether, propylene glycol diglycidyl ether, and polyglycidyl ether of polyether polyol synthesized by adding one or two or more alkylene oxides to a polyhydric alcohol such as ethylene glycol, propylene glycol, or glycerin.

Examples of the oxetane compound include: monofunctional oxetane compounds such as 3-(meth)allyloxymethyl-3-ethyloxetane, isobornyloxyethyl (3-ethyl-3-oxetanylmethyl) ether, isobornyl (3-ethyl-3-oxetanylmethyl) ether, 2-ethylhexyl (3-ethyl-3-oxetanylmethyl) ether, and dicyclopentadiene (3-ethyl-3-oxetanylmethyl) ether; difunctional oxetane compounds such as 3,7-bis(3-oxetanyl)-5-oxa-nonane, 1,2-bis[(3-ethyl-3-oxetanylmethoxy)methyl]ethane, 1,2-bis[(3-ethyl-3-oxetanylmethoxy)methyl]propane, dicyclopentenyl bis(3-ethyl-3-oxetanylmethyl) ether, 1,4-bis[(3-ethyl-3-oxetanylmethoxy)methyl]butane, and 1,6-bis[(3-ethyl-3-oxetanylmethoxy)methyl]hexane; and polyfunctional oxetane compounds such as trimethylolpropane tris(3-ethyl-3-oxetanylmethyl) ether, pentaerythritol tris(3-ethyl-3-oxetanylmethyl) ether, pentaerythritol tetrakis(3-ethyl-3-oxetanylmethyl) ether, and dipentaerythritol hexakis(3-ethyl-3-oxetanylmethyl) ether.

The component (C) preferably comprises a cyclic epoxy resin.

In the case of using the component (C), the amount of the component (C) contained is not particularly limited and can be appropriately adjusted and used. The sealant composition preferably comprises 10 to 90 parts by mass of the component (A) (i.e., 90 to 10 parts by mass of the component (C)) per 100 parts by mass in total of the component (A) and the component (C). This is effective for improving screen printability.

The component (C) may be used singly or in combinations of two or more thereof.

The sealant composition according to the disclosure preferably further comprises (D) an acid anhydride and/or (E) a radical photoinitiator. This is effective for being able to accelerate the curing of the sealant composition by heating. Examples thereof include heating during the preparation of a TiO₂ layer.

<Component (D)>

The component (D) is an acid anhydride and is an optional component. The acid anhydride is not particularly limited, and an acid anhydride known in the art can be appropriately selected and used.

Examples of the component (D) include derivatives of succinic anhydride, maleic anhydride or glutaric anhydride. Examples thereof include: alicyclic acid anhydrides such as succinic anhydride, dodecenyl succinic anhydride, maleic anhydride, methyltetrahydrophthalic anhydride, tetrahydrophthalic anhydride, methylhexahydrophthalic anhydride, hexahydrophthalic anhydride, trialkyltetrahydrophthalic anhydride, 5-norbornene-2,3-dicarboxylic anhydride, norbornane-2,3-dicarboxylic anhydride, methyl-5-norbornene-2,3-dicarboxylic anhydride, and methyl-norbornane-2,3-dicarboxylic anhydride; aromatic acid anhydrides such as phthalic anhydride, trimellitic anhydride, and pyromellitic anhydride; 2,4-diethylglutaric anhydride; acid dianhydrides such as methylcyclohexenetetracarboxylic dianhydride, benzophenonetetracarboxylic dianhydride, and ethylene glycol bis-anhydro trimellitate; and aliphatic cyclic saturated acid anhydrides having a 5-membered ring at an acid anhydride site and having a saturated 6-membered ring or a cross-linked structure.

The amount of the component (D) is not particularly limited and can be appropriately adjusted. For example, the ratio of the epoxy groups of the component (A) and the component (C) to the functional group of the component (D) (epoxy group/acid anhydride group) is preferably 0.6 to 2.0, more preferably 0.8 to 1.5.

The component (D) may be used singly or in combinations of two or more thereof.

<Component (E)>

The component (E) is a radical photoinitiator and is an optional component. The component (E) is not particularly limited, and a radical photoinitiator known in the art can be used.

Examples of the component (E) include: acetophenones such as acetophenone, 2,2-diethoxyacetophenone, m-chloroacetophenone, p-tert-butyltrichloroacetophenone, and 4-dialkylacetophenone; benzophenones such as benzophenone; Michler's ketones such as Michler's ketone; benzyls such as benzyl and benzyl methyl ether; benzoins such as benzoin and 2-methylbenzoin; benzoin ethers such as benzoin methyl ether, benzoin ethyl ether, benzoin isopropyl ether, and benzoin butyl ether; benzyl dimethyl ketals such as benzyl dimethyl ketal; thioxanthones such as thioxanthone, 2-chlorothioxanthone, and 4-isopropylthioxanthone; fluorenes such as 2-hydroxy-9-fluorenone; anthraquinones such as anthraquinone, 2-ethylanthraquinone, 2-hydroxyanthraquinone, and 2-aminoanthraquinone; various carbonyl compounds such as propiophenone, anthraquinone, acetoin, butyroin, toluoin, benzoyl benzoate, and α-acyloxime ester; sulfur compounds such as tetramethyl thiuram disulfide, tetramethyl thiuram monosulfide, and diphenyl disulfide; azo compounds such as azobisisobutyronitrile and azobis-2,4-dimethylvaleronitrile; and peroxides such as benzoyl peroxide and di-tert-butyl peroxide. Other examples thereof include: phenyl glyoxylates; acylphosphine oxides such as bis(2,4,6-trimethylbenzoyl)-phenylphosphine oxide; organic dye compounds such as organoboron compounds; and iron-phthalocyanine compounds.

The component (E) may be used singly or in combinations of two or more thereof. Among them, a compound capable of also exhibiting the effect of a sensitizer as a component (G) mentioned later may be used as a sensitizer. Particularly, acetophenones, benzophenones, thioxanthones, fluorenes, anthraquinones, organic dye compounds, iron-phthalocyanine compounds, and the like can also be used as sensitizers.

The amount of the component (E) is not particularly limited and can be appropriately adjusted. The amount is, for example, usually 0.1 parts by mass or more, preferably 1 part by mass or more and is usually 10 parts by mass or less, preferably 5 parts by mass or less, per 100 parts by mass in total of the component (A) and the component (C).

The component (E) may be used singly or in combinations of two or more thereof.

The sealant composition for an organic solar cell according to the disclosure preferably further comprises (F) a filler. This is effective for enhancing a mechanical property.

<Component (F)>

The component (F) is a filler and is an optional component. The component (F) is effective for enhancing a mechanical property. The component (F) is not particularly limited, and a filler selected from an inorganic filler and an organic filler known in the art can be used.

Examples of the inorganic filler include: oxide-based fillers such as silica, fine silicic acid powders, alumina, magnesium oxide, barium oxide, and calcium oxide; carbons such as carbon black and graphite; hydroxide-based fillers such as aluminum hydroxide and magnesium hydroxide; sedimentary rock-based fillers such as diatomite and limestone; clay mineral-based fillers such as kaolinite and montmorillonite; magnetic fillers such as ferrite, iron, and cobalt; conductive fillers such as silver, gold, copper, alloys, and gold-plated silica, glass beads, or resin particles such as polystyrene or acrylic resin particles; and light calcium carbonate, heavy calcium carbonate, talc, and clay.

The type of the silica is not particularly limited and can be appropriately selected. Examples thereof include fumed silica and precipitated silica.

The type of the carbon black is not particularly limited and can be appropriately selected. Examples thereof include SRF, GPF, FEF, HAF, ISAF, SAF, FT, and MT.

Examples of the organic filler include silicone fillers, epoxy resin fillers, polyamide fiber, and cross-linked rubber particles.

The component (F) may or may not be surface-treated, or may be a combination thereof. The component (F) is preferably surface-treated. The approach for surface treatment is not particularly limited, and an approach for surface treatment known in the art can be used. The component (F) may be surface-treated using, for example, a silane coupling agent; reactive silane such as hexamethyldisilazane, chlorosilane, or alkoxysilane; or low-molecular-weight siloxane.

Examples of the silane coupling agent can include 3-acryloyloxypropyltrimethoxysilane, 3-methacryloyloxypropyltrimethoxysilane, 3-acryloyloxypropyltriethoxysilane, 3-methacryloyloxypropyltriethoxysilane, 3-acryloyloxypropylmethyldimethoxysilane, 3-methacryloyloxypropylmethyldimethoxysilane, 3-acryloyloxypropylmethyldiethoxysilane, 3-methacryloyloxypropylmethyldiethoxysilane; 3-isocyanatopropyltriethoxysilane, 3-isocyanatopropyltrimethoxysilane, 3-isocyanatopropylmethyldiethoxysilane, 3-isocyanatopropylmethyldimethoxysilane; p-styryltrimethoxysilane, p-styryltriethoxysilane; vinyltrimethoxysilane, vinyltriethoxysilane, vinyltriisopropoxysilane, vinyltris(2-methoxyethoxy)silane; 2-(3,4-epoxycyclohexyl)ethyltrimethoxysilane, 3-glycidoxypropyltrimethoxysilane, 3-glycidoxypropylmethyldimethoxysilane, 3-glycidoxypropyltriethoxysilane, 3-glycidoxypropylmethyldiethoxysilane; N-2-(aminoethyl)-3-aminopropylmethyldimethoxysilane, N-(2-aminoethyl)-3-aminopropyltrimethoxysilane, N-(2-aminoethyl)-3-aminopropyltriethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane; 3-mercaptopropyltrimethoxysilane, 3-mercaptopropyltriethoxysilane, and allyltrimethoxysilane.

The silane coupling agent is preferably a silane coupling agent having an epoxy group, such as 2-(3,4-epoxycyclohexyl)ethyltrimethoxysilane, 3-glycidoxypropyltrimethoxysilane, 3-glycidoxypropylmethyldimethoxysilane, 3-glycidoxypropyltriethoxysilane, or 3-glycidoxypropylmethyldiethoxysilane; or a silane coupling agent having an amino group, such as N-2-(aminoethyl)-3-aminopropylmethyldimethoxysilane, N-(2-aminoethyl)-3-aminopropyltrimethoxysilane, N-(2-aminoethyl)-3-aminopropyltriethoxysilane, 3-aminopropyltrimethoxysilane, 3-aminopropyltriethoxysilane, 3-triethoxysilyl-N-(1,3-dimethyl-butylidene)propylamine, or N-phenyl-3-aminopropyltrimethoxysilane.

The amount of the component (F) is not particularly limited and can be appropriately adjusted. The sealant composition preferably comprises 0.1 to 1000 parts by mass of the filler (F) per 100 parts by mass in total of the component (A) and the component (C). The central particle diameter is usually 0.001 to 100 μm, preferably 0.005 to 50 μm, more preferably 0.01 to 20 μm.

The component (F) may be used singly or in combinations of two or more thereof.

The sealant composition for an organic solar cell according to the disclosure preferably further comprises (G) a sensitizer. This can control the wavelength of the active energy line used and is effective for enhancing the efficiency of an anion to be generated. The sensitizer as the component (G) can be any compound that increases the activity of the composition against light by combination with the component (B), and is not limited by the types of various sensitization mechanisms such as energy transfer, electron transfer, and proton transfer. Particularly, an aromatic hydrocarbon such as a fluonone compound, an anthrone compound, a fluorene compound, a fluoranthene compound, a naphthalene compound, or an anthracene compound, or a dye such as a nitro compound, riboflavin, rose bengal, eosin, erythrosine, methylene blue, new methylene blue rose, or a vitamin (vitamin K1, etc.) is preferred from the viewpoint of having good compatibility with the component (B) and being excellent in photocurability.

(Other Optional Components)

The sealant composition may optionally comprise a compound having one or more radical polymerizable groups in the molecule, a solvent, a colorant, a flame retardant, a plasticizer, a polymerization inhibitor, an antioxidant, an antifoaming agent, a coupling agent, a leveling agent, a rheology controlling agent, a rubber, cross-linked rubber particles, and the like for use in sealant compositions, in addition to the components mentioned above.

The radical polymerizable group includes a vinyl group, an allyl group, an acryloyl group, a methacryloyl group, and the like. The compound having one or more radical polymerizable groups in the molecule is desirably a compound having one or more (meth)acryloyl groups in the molecule because of being excellent in a photo radical polymerizability in itself. The compound having one or more radical polymerizable groups in the molecule is not particularly limited by a monomer, an oligomer, or a polymer, etc., and a compound having a number-average molecular weight of 10000 or smaller is usually used. Examples thereof include 2-hydroxyethyl acrylate, 2-hydroxypropyl (meth)acrylate, 4-hydroxybutyl (meth)acrylate, 2-hydroxybutyl (meth)acrylate, isobutyl (meth)acrylate, t-butyl (meth)acrylate, isooctyl (meth)acrylate, lauryl (meth)acrylate, stearyl (meth)acrylate, isobornyl (meth)acrylate, cyclohexyl (meth)acrylate, 2-methoxyethyl (meth)acrylate, methoxy ethylene glycol (meth)acrylate, 2-ethoxyethyl (meth)acrylate, tetrahydrofurfuryl (meth)acrylate, benzyl (meth)acrylate, ethyl carbitol (meth)acrylate, phenoxyethyl (meth)acrylate, phenoxy diethylene glycol (meth)acrylate, phenoxy polyethylene glycol (meth)acrylate, methoxy polyethylene glycol (meth)acrylate, 2,2,2,-trifluoroethyl (meth)acrylate, 2,2,3,3,-tetrafluoropropyl (meth)acrylate, 1H,1H,5H,-octafluoropentyl (meth)acrylate, imide (meth)acrylate, methyl (meth)acrylate, ethyl (meth)acrylate, n-butyl (meth)acrylate, propyl (meth)acrylate, n-butyl (meth)acrylate, cyclohexyl (meth)acrylate, 2-ethylhexyl (meth)acrylate, n-octyl (meth)acrylate, isononyl (meth)acrylate, isomyristyl (meth)acrylate, 2-butoxyethyl (meth)acrylate, 2-phenoxyethyl (meth)acrylate, bicyclopentenyl (meth)acrylate, isodecyl (meth)acrylate, diethylaminoethyl (meth)acrylate, dimethylaminoethyl (meth)acrylate, 2-(meth)acryloyloxyethylsuccinic acid, 2-(meth)acryloyloxyethylhexahydrophthalic acid, 2-(meth)acryloyloxyethyl 2-hydroxypropylphthalate, glycidyl (meth)acrylate, 2-(meth)acryloyloxyethyl phosphate, 1,4-butanediol di(meth)acrylate, 1,3-butanediol di(meth)acrylate, 1,6-hexanediol di(meth)acrylate, 1,9-nonanediol di(meth)acrylate, 1,10-decanediol di(meth)acrylate, 2-n-butyl-2-ethyl-1,3-propanediol di(meth)acrylate, dipropylene glycol di(meth)acrylate, tripropylene glycol di(meth)acrylate, polypropylene glycol (meth)acrylate, ethylene glycol di(meth)acrylate, diethylene glycol di(meth)acrylate, tetraethylene glycol di(meth)acrylate, polyethylene glycol di(meth)acrylate, propylene oxide-added bisphenol A di(meth)acrylate, bisphenol A di(meth)acrylate, ethylene oxide-added bisphenol A di(meth)acrylate, ethylene oxide-added bisphenol F di(meth)acrylate, dimethylol dicyclopentadienyl di(meth)acrylate, 1,3-butylene glycol di(meth)acrylate, neopentyl glycol di(meth)acrylate, ethylene oxide-modified isocyanuric acid di(meth)acrylate, 2-hydroxy-3-(meth)acryloyloxypropyl (meth)acrylate, carbonate diol di(meth)acrylate, pentaerythritol tri(meth)acrylate, trimethylolpropane tri(meth)acrylate, propylene oxide-added trimethylolpropane tri(meth)acrylate, ethylene oxide-added trimethylolpropane tri(meth)acrylate, caprolactone-modified trimethylolpropane tri(meth)acrylate, ethylene oxide-added isocyanuric acid tri(meth)acrylate, dipentaerythritol penta(meth)acrylate, dipentaerythritol hexa(meth)acrylate, ditrimethylolpropane tetra(meth)acrylate, pentaerythritol tetra(meth)acrylate, glycerin tri(meth)acrylate, propylene oxide-added glycerin tri(meth)acrylate, tris(meth)acryloyloxyethyl phosphate, and urethane (meth)acrylate (e.g., aliphatic urethane acrylate). Among them, propylene oxide-added bisphenol A di(meth)acrylate, bisphenol A di(meth)acrylate, bisphenol F di(meth)acrylate, ethylene oxide-added bisphenol A di(meth)acrylate, ethylene oxide-added bisphenol F di(meth)acrylate, or urethane (meth)acrylate is preferably used from the viewpoint of compatibility with the component (A). The amount of these compounds contained is not particularly limited and is preferably 0.1 to 200 parts by mass per 100 parts by mass in total of the component (A) and the component (C) of the disclosure.

According to the disclosure, a compound or a radical polymerization inhibitor effective for suppressing arbitrary anionic polymerization may be added as a polymerization inhibitor without impairing the characteristics of the disclosure. This polymerization inhibitor is added in order to increase the stability of the composition during storage. The polymerization inhibitor is, for example, an organic or inorganic acid that is in a liquid or solid state at room temperature, an oligomer or a polymer having an acidic group in the molecule, a boric acid ester, or a phosphoric acid ester and may have a functional group other than the acidic group. Examples thereof include, but are not limited to, sulfuric acid, acetic acid, adipic acid, tartaric acid, fumaric acid, barbituric acid, boric acid, pyrogallol, phenol resins, and carboxylic anhydride.

<Method for Preparing Sealant Composition for an Organic Solar Cell>

The method for preparing the sealant composition for an organic solar cell is not particularly limited, and the sealant composition for an organic solar cell can be prepared by use of a method known in the art. The sealant composition for an organic solar cell can be prepared, for example, by mixing the component (A), the component (B) and the component (C) mentioned above, and if necessary, other components using a mixing apparatus known in the art such as a sand mill, a disper blade, a collide mill, a planetary mixer, a kneader, or a triple roll mill.

The sealant for an organic solar cell according to the disclosure is preferably a cured product of any of the sealant compositions for an organic solar cell described above. This sealant is excellent in adhesiveness to a current collecting wire and has highly reliable sealing performance.

The curing means is preferably photocuring with active energy line, for example, visible light, ultraviolet ray, near infrared radiation, far-infrared radiation, or electron beam and may be arbitrarily used in combination with heat treatment. The light source includes a high-pressure mercury lamp, an ultrahigh-pressure mercury lamp, a metal halide lamp, a gallium lamp, a xenon lamp, a carbon arc lamp, and the like. For example, the curing of the sealant can be accelerated by heating during the preparation of a TiO₂ layer. The wavelength of the light does not have to be a single wavelength and can be appropriately selected according to the characteristics of the component (B) used, etc. The integrated dose of the active energy line is usually 0.1 mJ/cm² to 10000 mJ/cm², preferably 1 mJ/cm² to 4000 mJ/cm². The wavelength of the active energy line is preferably 150 to 830 nm. The heating conditions preferably involve room temperature to 250° C., more preferably 50 to 200° C., further preferably 70 to 150° C. The energy line irradiation and the heating may be performed at the same time or may be performed separately. After the energy line irradiation, the sealant may be left at room temperature to thereby accelerate its curing. The irradiation can be carried out in an appropriately selected atmosphere such as vacuum, air, or an inert gas such as nitrogen.

The sealant for an organic solar cell according to the disclosure is preferably prepared by curing any of the sealant compositions for an organic solar cell described above by light irradiation, followed by further curing by heating. The curing of the sealant is accelerated by the heating, and the resulting sealant has enhanced adhesiveness to a current collecting wire and has highly reliable sealing performance.

<Electrode for Organic Solar Cell>

The electrode for an organic solar cell according to the disclosure is an electrode for an organic solar cell, comprising:

a substrate;

a current collecting wire on the substrate; and

a sealant covering the current collecting wire, wherein

the current collecting wire is a photocured product, and

the sealant is a photocured product of any of the sealant compositions for an organic solar cell described above.

The electrode comprising such a photocured product is excellent in the adhesiveness between a sealant and a current collecting wire and has high reliability. Examples of such an electrode for an organic solar cell include a photoelectrode and a counter electrode for the current collecting wiring module mentioned above.

Hereinafter, a substrate (comprising a conductive film), a current collecting wire and a sealant in the electrode for an organic solar cell as one example will be described.

<Substrate>

The substrate is not particularly limited, and an electrode substrate for an organic solar cell known in the art can be appropriately selected and used. Examples thereof include conductive films having a substrate such as a transparent resin or glass coated with a metal (Au, Ag, Cu, etc.) mesh conductive film or metal (Ag, Ag wire, etc.) nanoparticles, conductive films of composite metal oxide such as indium tin oxide (ITO), indium zinc oxide (IZO), or fluorine-doped tin (FTO), carbon-based conductive films such as carbon nanotubes and graphene, conductive polymer films such as PEDOT/PSS, and products prepared by stacking conductive films consisting of layers containing a mixture or a stack thereof.

Examples of the transparent resin include synthetic resins such as polyethylene terephthalate (PET), polyethylene naphthalate (PEN), syndiotactic polystyrene (SPS), polyphenylene sulfide (PPS), polycarbonate (PC), polyarylate (PAr), polysulfone (PSF), polyester sulfone (PES), polyetherimide (PEI), transparent polyimide (PI), cycloolefin polymer (COP), and polymethylpentene (TPX).

The electrode for an organic solar cell according to the disclosure can also be suitably used when the substrate is a flexible substrate.

<Current Collecting Wire>

The current collecting wire is provided on at least a portion of the substrate.

The current collecting wire is not particularly limited, and a current collecting wire known in the art can be appropriately selected and used. The current collecting wire can be prepared by, for example, a coating method such as sputtering, deposition, plating, or inkjet or screen printing using a photocurable and/or thermosetting conductive paste. Examples of the conductive paste include known compositions containing a conductive material such as a metal (e.g., silver and copper), a metal oxide, or a conductive carbon material (e.g., graphene and carbon nanotubes), and a curable resin that is cured by irradiation with active radiation or ultraviolet ray, or heating. Among others, a conductive paste having at least photocurability is preferred because of being excellent in workability and productivity. Examples of the curable resin include curable silicone resins, curable epoxy resins, curable urethane resins, and curable (meth)acrylic resins. An arbitrary curing agent, such as a radical initiator, a cationically curing agent, or an anionically curing agent, which acts by irradiation with active radiation or ultraviolet ray, or heating can be used in the resin.

<Sealant>

The sealant covers the current collecting wire and protects the current collecting wire from an electrolyte. The sealant is a photocured product of any of the sealant compositions for an organic solar cell described above. The electrode comprising such a photocured product is excellent in the adhesiveness between a sealant and a current collecting wire and has high reliability.

For the electrode for an organic solar cell according to the disclosure, it is preferred that the electrode for an organic solar cell should be a photoelectrode, wherein the photoelectrode comprises a porous semiconductor fine particle layer and

is prepared by photocuring the current collecting wire and the sealant, then coating the substrate with a material for the porous semiconductor fine particle layer, and heating the sealant and the material for the porous semiconductor fine particle layer to form the porous semiconductor fine particle layer.

The curing of the sealant is accelerated by the heating in forming the porous semiconductor fine particle layer, and the resulting electrode has improved adhesiveness between a sealant and a current collecting wire and has high reliability.

Hereinafter, the porous semiconductor fine particle layer comprising a sensitizing dye layer will be illustrated and described.

<Porous Semiconductor Fine Particle Layer>

The porous semiconductor fine particle layer is a porous layer containing semiconductor fine particles. The porous layer increases the amount of the sensitizing dye adsorbed and facilitates obtaining a dye-sensitized solar cell having high conversion efficiency.

Examples of the semiconductor fine particles include particles of metal oxides such as titanium oxide, zinc oxide, and tin oxide. The semiconductor fine particles are preferably titanium oxide. A layer containing titanium oxide adopted as the semiconductor fine particles is a titanium oxide layer.

The particle diameter (average particle diameter of primary particles) of the semiconductor fine particles is not particularly limited and can be appropriately adjusted. The particle diameter is preferably 2 to 80 nm, more preferably 2 to 60 nm. A small particle diameter can reduce resistance.

The thickness of the porous semiconductor fine particle layer is not particularly limited and is usually 0.1 to 50 μm, preferably 5 to 30 μm.

The method for forming the porous semiconductor fine particle layer is not particularly limited, and a method known in the art can be appropriately selected and used. The porous semiconductor fine particle layer can be formed by a method known in the art, for example, a press process, a hydrothermal decomposition process, an electrophoretic deposition process, or a binder-free coating process.

The heating temperature in forming the porous semiconductor fine particle layer is not particularly limited and can be appropriately adjusted. The heating temperature is usually 100 to 600° C. and is 200° C. or lower, preferably 160° C. or lower, in the case of using a plastic or the like as the substrate.

The sensitizing dye layer is a layer prepared by adsorbing a compound capable of transferring electrons to the porous semiconductor fine particle layer by excitation with light (sensitizing dye) onto the surface of the porous semiconductor fine particle layer.

The sensitizing dye is not particularly limited, and a sensitizing dye for dye-sensitized solar cells known in the art can be appropriately selected and used. Examples thereof include: organic dyes such as cyanine dyes, merocyanine dyes, oxonol dyes, xanthene dyes, squarylium dyes, polymethine dyes, coumarin dyes, riboflavin dyes, and perylene dyes; and metal complex dyes such as phthalocyanine complexes and porphyrin complexes of metals such as iron, copper, and ruthenium. Typical examples of the sensitizing dye include N3, N719, N749, D102, D131, D150, N205, HRS-1, and MK-2. It is preferred that an organic solvent that dissolves the dye should be degassed and distilled and purified in advance in order to remove water and gases present in the solvent. The solvent is preferably a solvent including: alcohols such as methanol, ethanol, and propanol; nitriles such as acetonitrile; and halogenated hydrocarbons, ethers, amides, esters, carbonic acid esters, ketones, hydrocarbons, aromatic solvents, and nitromethane.

The method for forming the sensitizing dye layer is not particularly limited, and a method known in the art can be appropriately selected and used. The sensitizing dye layer can be formed by a method known in the art, for example, a method of dipping the porous semiconductor fine particle layer in a solution of the sensitizing dye, or a method of coating the porous semiconductor fine particle layer with a solution of the sensitizing dye.

In the case of using the electrode for an organic solar cell as a counter electrode, a counter electrode configuration known in the art, such as a support or a catalyst layer, other than the sealant covering the current collecting wire may be appropriately adopted, or a counter electrode configuration mentioned later may be adopted.

<Organic Solar Cell>

The organic solar cell according to the disclosure is preferably an organic solar cell prepared by using any of the sealant compositions for an organic solar cell described above. This organic solar cell is excellent in the adhesiveness between a sealant and a current collecting wire and has high reliability.

Examples of the organic solar cell include dye-sensitized solar cells and perovskite solar cells.

The organic solar cell can employ a sealant obtained from any of the sealant compositions for an organic solar cell described above, for example, instead of a sealant that is used in the sealing of an electrolyte layer or the protection of a current collecting wire in conventional organic solar cells, and can employ those known in the art as other organic solar cell configurations such as electrodes (photoelectrode and counter electrode), an electrolyte layer (electrolyte and solvent), an antireflection layer, and a gas barrier layer. Hereinafter, the photoelectrode, the electrolyte layer and the counter electrode described above will be described by taking a dye-sensitized solar cell as one example of the organic solar cell.

<Photoelectrode>

The photoelectrode can be any electrode capable of releasing electrons to an outside circuit by receiving light, and a photoelectrode known in the art can be used for the dye-sensitized solar cell. A photoelectrode having the configuration of the electrode for an organic solar cell according to the disclosure mentioned above may be used.

<Electrolyte Layer>

The electrolyte layer is a layer for separating the photoelectrode from a counter electrode while efficiently performing charge transfer. The electrolyte layer is not particularly limited by a solid, a liquid, or a semisolid such as a gel. The electrolyte layer usually contains a supporting electrolyte, a redox couple (a pair of chemical species capable of being mutually reversibly converted in the forms of an oxidant and a reductant in redox reaction), a solvent, and the like.

Examples of the supporting electrolyte include ionic liquids containing salts of alkali metals (lithium ions, etc.), alkaline earth metals, or the like, imidazolium ions, compounds having a quaternary nitrogen atom as a spiro atom, cations such as quaternary ammonium ions.

A redox couple known in the art can be used as long as the redox couple is capable of reducing an oxidized sensitizing dye. Examples of the redox couple include chlorine compound-chlorine, iodine compound-iodine, bromine compound-bromine, thallium ion(III)-thallium ion(I), ruthenium ion(III)-ruthenium ion(II), copper ion(II)-copper ion(I), iron ion(III)-iron ion(II), cobalt ion(III)-cobalt ion(II), vanadium ion(III)-vanadium ion(II), manganate ion-permanganate ion, ferricyanide-ferrocyanide, quinone-hydroquinone, and fumaric acid-succinic acid.

A solvent known in the art for the formation of electrolyte layers for solar cells can be used as the solvent. Examples of the solvent include acetonitrile, methoxyacetonitrile, methoxypropionitrile, N,N-dimethylformamide, ethyl methylimidazolium bistrifluoromethylsulfonylimide, propylene carbonate, glycol ether, and γ-butyrolactone.

The method for forming the electrolyte layer is not particularly limited, and a method known in the art can be appropriately selected and used. The electrolyte layer can be formed, for example, by coating a photoelectrode with a solution containing a component constituting the electrolyte layer (electrolyte solution); or preparing a cell having a photoelectrode and a counter electrode and injecting an electrolyte solution to a gap therebetween.

<Counter Electrode>

A counter electrode known in the art can be appropriately selected and used as the counter electrode. Examples thereof include counter electrodes having a conductive film and a catalyst layer in this order on a support.

The support plays a role in supporting the catalyst layer. Examples of the support include: conductive sheets formed using metals, metal oxides, carbon materials, conductive polymers, or the like; and nonconductive sheets made of a transparent resin or glass.

Examples of the transparent resin include the transparent resins listed in the photoelectrode described above.

Examples of the conductive film include those made of: metals such as platinum, gold, silver, copper, aluminum, indium, and titanium; conductive metal oxides such as tin oxide and zinc oxide; composite metal oxides such as indium tin oxide (ITO), indium zinc oxide (IZO), and fluorine-doped tin (FTO); carbon materials such as carbon nanotubes, carbon nanobuds, graphene, and fullerene; and combinations of two or more thereof.

The catalyst layer functions as a catalyst when electrons are transferred from the counter electrode to the electrolyte layer in the organic solar cell. A catalyst layer known in the art can be appropriately selected and used as the catalyst layer. The catalyst layer preferably contains, for example, a conductive polymer, a carbon nanostructure, and noble metal particles having a catalytic effect, or both a carbon nanostructure and noble metal particles.

Examples of the conductive polymer can include: polythiophenes such as poly(thiophene-2,5-diyl), poly(3-butylthiophene-2,5-diyl), poly(3-hexylthiophene-2,5-diyl), and poly(2,3-dihydrothieno-[3,4-b]-1,4-dioxin) (PEDOT); polyacetylene and its derivatives; polyaniline and its derivatives; polypyrrole and its derivatives; and polyphenylenevinylenes such as poly(p-xylene tetrahydrothiophenium chloride), poly[(2-methoxy-5-(2′-ethylhexyloxy))-1,4-phenylenevinylene], poly[(2-methoxy-5-(3′,7′-dimethyloctyloxy)-1,4-phenylenevinylene)], and poly[2-2′,5′-bis(2″-ethylhexyloxy)phenyl]-1,4-phenylenevinylene].

Examples of the carbon nanostructure can include natural graphite, activated carbon, artificial graphite, graphene, carbon nanotubes, and carbon nanobuds.

The noble metal particles are not particularly limited as long as the noble metal particles have a catalytic effect. Noble metal particles known in the art can be appropriately selected and used. Examples thereof include metal platinum, metal palladium and metal ruthenium.

The method for forming the catalyst layer is not particularly limited, and a method known in the art can be appropriately selected and used. The method can be performed, for example, by dissolving or dispersing the conductive polymer, the carbon nanostructure, or the noble metal particles, or both the carbon nanostructure and the noble metal particles in an appropriate solvent, applying or spraying the obtained mixed solution onto a conductive film, and drying the solvent in the mixed solution. In the case of using the carbon nanostructure and/or the noble metal particles, the mixed solution may further contain a binder. A polymer having, for example, a functional group such as a hydroxy group, a carboxyl group, a sulfonyl group, or a phosphate group, or a sodium salt of the functional group is preferably used as the binder from the viewpoint of the dispersibility of the carbon nanostructure and close adherence to the substrate.

The catalyst layer may contain a carbon nanotube whose average diameter (Av) and standard deviation (σ) of diameter satisfy 0.60>3σ/Av>0.20 (hereinafter, also referred to as the expression (A)) (hereinafter, also referred to as a “specific carbon nanotube”). In this context, the “specific carbon nanotube” is a collective term for a population of predetermined carbon nanotubes constituting it, and the “diameter” means the outside diameters of the predetermined carbon nanotubes.

The average diameter (Av) and standard deviation (σ) of diameter of the specific carbon nanotube are a sample average value and a sample standard deviation, respectively. They are determined as an average value and a standard deviation of the diameters of 100 randomly selected carbon nanotubes measured by observation under a transmission electron microscope. 3σ in the expression (A) is determined by multiplying the obtained standard deviation (σ) by 3.

A counter electrode having excellent catalytic activity can be obtained by using the specific carbon nanotube. 0.60>3σ/Av>0.25 is preferred, and 0.60>3σ/Av>0.50 is more preferred, from the viewpoint of improving the characteristics of the resulting counter electrode.

3σ/Av represents the diameter distribution of the specific carbon nanotube. A larger value of this 3σ/Av means a wider diameter distribution. The diameter distribution preferably assumes a normal distribution. In this case, the diameter distribution can be observed under a transmission electron microscope and is obtained by measuring the diameters of 100 randomly selected carbon nanotubes, and plotting the obtained data with diameter on the abscissa against frequency on the ordinate using the results, followed by Gaussian approximation. The value of 3σ/Av may be increased by combining a plurality of carbon nanotubes, etc. obtained by different production methods. In this case, however, it is difficult to obtain a normal distribution as the diameter distribution. The specific carbon nanotube may consist of one type of carbon nanotube or may be one type of carbon nanotube supplemented with different carbon nanotubes in an amount that does not influence the diameter distribution.

The average diameter (Av) of the specific carbon nanotube is preferably 0.5 nm or larger and 15 nm or smaller, more preferably 1 nm or larger and 10 nm or smaller, from the viewpoint of obtaining excellent catalytic activity.

The average length of the specific carbon nanotube is preferably 0.1 μm to 1 cm, more preferably 0.1 μm to 1 mm. When the average length of the specific carbon nanotube falls within the range described above, a highly active catalyst layer is easily formed. The average length of the specific carbon nanotube can be calculated, for example, by measuring 100 randomly selected carbon nanotubes under a transmission electron microscope.

The specific surface area of the specific carbon nanotube is preferably 100 to 2500 m²/g, more preferably 400 to 1600 m²/g. When the specific surface area of the specific carbon nanotube falls within the range described above, a highly active catalyst layer is easily formed. The specific surface area of the specific carbon nanotube can be determined by a nitrogen gas adsorption method.

The carbon nanotubes constituting the specific carbon nanotube may have a single wall or may have multiple walls. Single-walled to 5-walled carbon nanotubes are preferred from the viewpoint of improving the activity of the catalyst layer.

The carbon nanotubes constituting the specific carbon nanotube may contain a functional group such as carboxyl group introduced to the surface. The introduction of the functional group can be performed by an oxidation treatment method known in the art using hydrogen peroxide, nitric acid, or the like.

The specific carbon nanotube can be obtained by a method known in the art, for example, a method of supplying a starting compound and a carrier gas onto a substrate having a catalyst layer for carbon nanotube production (hereinafter, also referred to as a “catalyst layer for CNT production”) on the surface (hereinafter, also referred to as a “substrate for CNT production”), and synthesizing carbon nanotubes by chemical vapor deposition (CVD) in the presence of a trace amount of an oxidizing agent in the system to thereby drastically improve the catalytic activity of the catalyst layer for CNT production (super growth method) (e.g., International Publication No. WO 2006/011655). Hereinafter, the carbon nanotube produced by the super growth method is also referred to as SGCNT.

The catalyst layer constituted by the specific carbon nanotube as a material has sufficient activity even if containing no metal. Thus, the catalyst layer may not contain a metal. However, the specific carbon nanotube may support a trace amount of nanosized platinum or the like. In this case, improvement in catalytic effect is improved. The supporting of the metal by the carbon nanotubes can be performed according to a method known in the art.

The thickness of the catalyst layer is preferably 0.005 μm to 100 μm.

The amount of the specific carbon nanotube contained in the catalyst layer is preferably 0.1 to 2×10⁴ mg/m², more preferably 0.5 to 5×10³ mg/m².

The counter electrode comprising the catalyst layer constituted by the specific carbon nanotube as a material can be prepared, for example, by preparing a dispersion liquid containing the specific carbon nanotube, coating a substrate with this dispersion liquid, and drying the obtained coating film to form the catalyst layer.

Examples of the solvent for use in the preparation of the dispersion liquid include: water; alcohols such as methanol, ethanol, and propanol; ketones such as acetone and methyl ethyl ketone; ethers such as tetrahydrofuran, dioxane, and diglyme; amides such as N,N-dimethylformamide, N,N-dimethylacetamide, N-methyl-2-pyrrolidone, and 1,3-dimethyl-2-imidazolidinone; and sulfur-containing solvents such as dimethyl sulfoxide and sulfolane. These solvents can be used singly or in combinations of two or more thereof.

The dispersion liquid may contain a dispersant for improving the dispersibility of the specific carbon nanotube. Preferred examples of the dispersant include: ionic surfactants known in the art; nonionic surfactants such as carboxyl methyl cellulose (CMC) and carboxyl methyl cellulose salt; and polymer activators such as polystyrenesulfonates such as sodium polystyrenesulfonate.

The dispersion liquid may further contain a binder, a conductive additive, a surfactant, and the like. Those known in the art can be appropriately used thereas.

The dispersion liquid can be obtained, for example, by mixing the specific carbon nanotube and if necessary, other components in a solvent to disperse the carbon nanotubes.

The mixing treatment or the dispersion treatment can employ a method known in the art. Examples thereof include methods using a nanomizer, an ultimizer, an ultrasonic disperser, a ball mill, a sand grinder, a dyno-mill, a spike mill, DCP MILL, a basket mill, a paint conditioner, or a high-speed stirring apparatus.

The content of the specific carbon nanotube in the dispersion liquid is not particularly limited and is preferably 0.001 to 10% by mass, more preferably 0.01 to 5% by mass, in the whole dispersion liquid.

<Others>

One or both of the photoelectrode layer and the counter electrode layer acting as electrodes may be provided with a functional layer such as an antifouling layer, a protective layer (hard coat, etc.), an antireflection layer, or a gas barrier layer. A thin film layer of a compact semiconductor (metal oxide TiO₂, SnO₂, Fe₂O₃, WO₃, ZnO, Nb₂O₅, etc.) may be provided as a foundation layer between the first electrode substrate and the porous semiconductor layer. Also, a separator for the prevention of short circuits may be contained therein.

<Extraction Electrode>

An extraction electrode can be established in order to extract current from the prepared module. Usually, the position, material, preparation method, etc. of the extraction electrode are not particularly limited and can be practiced by a method known in the art. Paste of a metal (aluminum, nickel, stainless steel, copper, gold, silver, solder, etc.) or carbon, conductive tape, or the like can be used as the material. These extraction electrodes can be appropriately prepared as extraction electrodes on the negative electrode and positive electrode sides from the photoelectrode and counter electrode sides, respectively.

The structure of the module is not particularly limited and includes Z type, W type, parallel type, current collecting sequence type, monolithic type, etc. One or two or more in combination of these modules may be connected in series or in parallel, and a plurality of such modules may be connected. Means known in the art can be used as a connection method, and solder, a metal plate, a cable, a flat cable, a flexible substrate, a cable, or the like can be appropriately selected.

In addition to the dye-sensitized solar cell mentioned above, examples of the perovskite solar cell include perovskite solar cells described in JP2014-049631A, JP2015-046583A, and JP2016-009737A.

<Method for Producing Solar Cell Module>

The method for producing the module is not particularly limited, and the module can be produced by a method known in the art such as one drop filling (ODF) or end sealing. Examples of the ODF include methods described in WO2007/046499. Examples of the end sealing include methods described in JP2006-004827A.

The organic solar cell according to the disclosure is preferably an organic solar cell comprising any of the electrodes for an organic solar cell described above. This organic solar cell is excellent in the adhesiveness between a sealant and a current collecting wire and has high reliability. In this organic solar cell, the electrode for an organic solar cell according to the disclosure can be used as an electrode (photoelectrode and/or counter electrode), and other configurations such as an electrolyte layer are the same as those mentioned above.

### Examples

Hereinafter, the disclosure will be described in more detail with reference to Examples. However, these Examples are intended to illustrate the disclosure and do not limit the disclosure by any means. The amount contained means parts by mass unless otherwise specified.

The detailed materials used in Examples are as follows.

### Component (A) (Hydrogenated Epoxy Resin)

Component (A) 1: product name jER® YX-8000 manufactured by Mitsubishi Chemical Corporation, viscosity: 1950 mPa·s, epoxy equivalent: 205
Component (A) 2: hydrogenated bisphenol resin: product name jER® YL-7717 manufactured by Mitsubishi Chemical Corporation, semisolid, epoxy equivalent: 190

### Component (B) (Photobase Generator)

Component (B) 1: 1,2-diisopropyl-3-[bis(dimethylamino)methylene]guanidium 2-(3-benzoylphenyl)propionate: product name WPBG-266 manufactured by Wako Pure Chemical Industries, Ltd.
Component (B) 2: 1,2-dicyclohexyl-4,4,5,5-tetramethylbiguanidium n-butyltriphenylborate: product name WPBG-300 manufactured by Wako Pure Chemical Industries, Ltd.
Component (C) (Anionically Curable Compound Other than the Component (A))
Component (C) 1: cyclic epoxy resin: product name Celloxide® 2021P manufactured by Daicel Corp. (3′,4′-epoxycyclohexylmethyl 3,4-epoxycyclohexanecarboxylate), viscosity: 300 mPa·S, epoxy equivalent: 133
Component (C) 2: hydroxyl group-containing aromatic bisphenol A: product name jER® 807 manufactured by Mitsubishi Chemical Corporation, viscosity: 3600 mPa·s, epoxy equivalent: 170

### Component (D) (Acid Anhydride)

Methyl-5-norbornene-2,3-dicarboxylic anhydride: manufactured by Wako Pure Chemical Industries, Ltd.

### Component (E) (Radical Photoinitiator)

1-Hydroxy cyclohexyl phenyl ketone: product name IRGACURE® 184 manufactured by BASF SE, absorption wavelength: 254 nm

### Component (F) (Filler)

Silica (silica surface-treated with 3-glycidoxypropyltrimethoxysilane): product name Admafine® SO-C5 manufactured by Admatechs Company Limited, central particle diameter: 1.6 μm

### Component (G) (Sensitizer)

Vitamin K1: manufactured by Wako Pure Chemical Industries, Ltd. Thermosetting curing agent
2-Ethyl-4(5)-methylimidazole: product name jER Cure® EMI24 manufactured by Mitsubishi Chemical Corporation

### Photo Cationic Generator

Aromatic sulfonium/antimony salt: product name ADEKA ARKLS® SP-170 manufactured by ADEKA Corp.
Binder-free titanium oxide paste: product name PECC-C01-06 manufactured by Peccell Technologies, Inc.
Sensitizing dye solution: sensitizing dye ruthenium complex (product name N719 manufactured by Solaronix SA), solvent: acetonitrile and tert-butanol, concentration: 0.4 mM

(Preparation of Sealant Composition)

Components were mixed according to the composition shown in Table 1 to prepare sealant compositions of Examples 1 to 15 and Comparative Examples 1 to 5.

(Preparation of Photoelectrode)

A conductive film (ITO) was formed on a photoelectrode substrate (PEN, 250 mm×250 mm). A current collecting wire (width: 200 μm, length: 30 mm, thickness: 20 μmm) was prepared on the conductive film using UV-curable Ag paste (RA FS FD 076 manufactured by Toyochem Co., Ltd.) and cured by UV irradiation. Subsequently, the current collecting wire surface was coated with each sealant composition by screen printing under the conditions given below so as to cover the current collecting wire. The screen printability at the time of the screen printing was visually evaluated according to the evaluation criteria given below. The evaluation results are also shown in Table 1.

Screen Printing Conditions

Mesh: 350 mesh (made of SUS)
Squeegee speed: 25 mm/sec
Squeegee angle: 20°

Screen Printability Evaluation Criteria

A: A uniform coating film was observed.
B: “Stringiness” or “fade” at the time of the screen printing or “contamination by foaming” in the resin coating film was observed.
C: The prepared composition was unable to be screen-printed due to a high viscosity.

In Examples 1, 4, 6, 8, 11, 13, and 15 and Comparative Examples 2 to 4, ITO-PEN after the screen printing was subsequently irradiated at integrated light intensity of 3000 mJ/cm² using an ultraviolet irradiation machine (254 nm) in air. Then, a sealant covering the current collecting wire was formed to obtain samples. Also, in Examples 2, 3, 5, 7, 9, 10, 12, and 14 and Comparative Examples 1 and 5, procedures to ultraviolet irradiation were performed in the same way as in Example 1, and a sealant covering the current collecting wire was formed by heating at 120° C. for 10 minutes after the ultraviolet irradiation to obtain samples.

Each of the samples of Examples and Comparative Examples was dipped for 7 days in a 3-methoxypropionitrile-based electrolyte solution containing 0.05 M iodine, kept at 65° C. The sample thus dipped was visually evaluated for its reliability (electrolyte solution resistance) according to the evaluation criteria given below. The evaluation results are also shown in Table 1.

Reliability Evaluation Criteria

A: No corrosion was confirmed in the current collecting wire.
B: Corrosion was confirmed in less than 10% of the current collecting wire.
C: Corrosion was confirmed in 10% or more of the current collecting wire.

Aside from this, ITO-PEN with a sealant (protective layer) formed according to the composition shown in Table 1 (i.e., neither dipping in an electrolyte solution nor heating at 120° C. for 10 minutes after ultraviolet irradiation was performed) was coated with titanium oxide paste by screen printing and heated at 150° C. for 10 minutes for drying. Subsequently, a sensitizing dye was adsorbed thereonto using a sensitizing dye solution.

(Preparation of Counter Electrode)

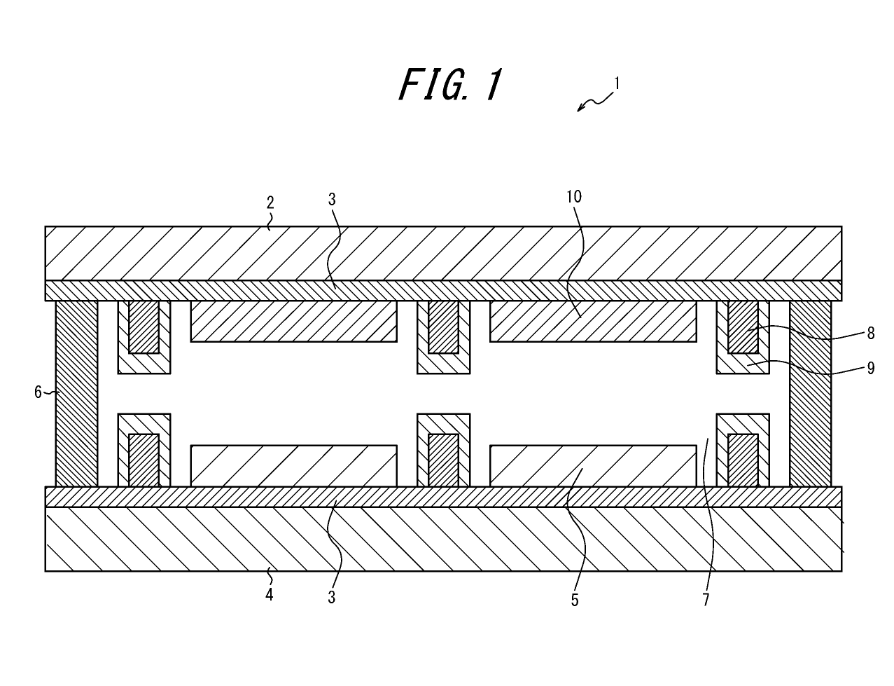

A protective layer composed of a current collecting wire and a sealant was prepared on ITO-PEN in the same way as in the preparation of the photoelectrode of Example 1 to prepare an electrode substrate. Subsequently, a site where the current collecting wire was absent on ITO-PEN was coated with a solution of a specific carbon nanotube, as in the counter electrode of FIG. 1, in the same way as the method described in the paragraph 0062 of JP2014-120219A so that a catalyst layer was formed to obtain a counter electrode.

(Preparation of Organic Solar Cell)

The photoelectrode was coated and completely surrounded with an encapsulant (photocurable polybutylene resin) as shown in FIG. 1 using a dispenser such that the width and height of the encapsulant after bonding in a vacuum bonding apparatus were 0.9 mm and 30 μM, respectively. Then, the titanium oxide layer was coated with an electrolyte solution. The counter electrode was loaded in a vacuum bonding apparatus and laminated therewith in a vacuum. The encapsulation material was cured by UV irradiation at integrated light intensity of 3000 mJ/cm² using a metal halide lamp to perform bonding. The apparatus was opened to atmospheric pressure from vacuum, and the organic solar cell was taken out thereof.

The positions of the photoelectrode substrate (lower substrate) and the counter electrode (upper substrate) were confirmed under an optical microscope, and the bonding accuracy was evaluated according to the criteria given below. The evaluation results are also shown in Table 1.

Bonding Accuracy Evaluation Criteria

A: The accuracy of upper and lower bonding positions was within ±20%.
B: The accuracy of upper and lower bonding positions was ±20% to ±30%.
C: The accuracy of upper and lower bonding positions exceeded ±30%.

TABLE 1

| | | Example 1 | Example 2 | Example 3 | Example 4 | Example 5 | Example 6 | Example 7 |
|---|---|---|---|---|---|---|---|---|
| Formulation of sealant | Component | 60 | 60 | 60 | 70 | 70 | 60 | 60 |
| composition (parts by mass) | (A) 1 | | | | | | | |
| | Component | 30 | 30 | 30 | | | | |
| | (A) 2 | | | | | | | |
| | Component | 3 | 3 | 3 | 3 | 3 | 3 | 3 |
| | (B) 1 | | | | | | | |
| | Component | | | | | | | |
| | (B) 2 | | | | | | | |
| | Component | | | | 30 | 30 | | |
| | (C) 1 | | | | | | | |
| | Component | 10 | 10 | 10 | | | 40 | 40 |
| | (C) 2 | | | | | | | |
| | Component | | | 2 | | | | |
| | (D) | | | | | | | |
| | Component | | | | | | | |
| | (E) | | | | | | | |
| | Component | 10 | 10 | 10 | 10 | 10 | 10 | 10 |
| | (F) | | | | | | | |
| | Component | | | | | | | |
| | (G) | | | | | | | |
| | Thermosetting | | | | | | | |
| | curing agent | | | | | | | |
| | Photo cationic | | | | | | | |
| | generator | | | | | | | |
| Presence or | | Absent | Present | Present | Absent | Present | Absent | Present |
| absence of | | | | | | | | |
| heat treatment | | | | | | | | |
| Evaluation | Screen | A | A | A | A | A | A | A |
| | printability | | | | | | | |
| | Reliability | B | A | A | B | A | B | B |
| | Bonding | A | A | A | A | A | A | A |
| | accuracy | | | | | | | |
| | | | | Example | Example | Example | Example | Example |
| | | Example 8 | Example 9 | 10 | 11 | 12 | 13 | 14 |
| Formulation of sealant | Component | 80 | 80 | 80 | 80 | 90 | 70 | 70 |
| composition (parts by mass) | (A) 1 | | | | | | | |
| | Component | | | 15 | 15 | | | |
| | (A) 2 | | | | | | | |
| | Component | 3 | 3 | 3 | 3 | 3 | | |
| | (B) 1 | | | | | | | |
| | Component | | | | | | 3 | 3 |
| | (B) 2 | | | | | | | |
| | Component | | | 5 | 5 | | 30 | 30 |
| | (C) 1 | | | | | | | |
| | Component | 20 | 20 | | | 10 | | |
| | (C) 2 | | | | | | | |
| | Component | | | | | | | |
| | (D) | | | | | | | |
| | Component | | | | | | | |
| | (E) | | | | | | | |
| | Component | 10 | 10 | 10 | 10 | 10 | 10 | 10 |
| | (F) | | | | | | | |
| | Component | | | | | | 1 | 1 |
| | (G) | | | | | | | |
| | Thermosetting | | | | | | | |
| | curing agent | | | | | | | |
| | Photo cationic | | | | | | | |
| | generator | | | | | | | |
| Presence or | | Absent | Present | Present | Absent | Present | Absent | Present |
| absence of | | | | | | | | |
| heat treatment | | | | | | | | |
| Evaluation | Screen | B | B | B | B | B | A | A |
| | printability | | | | | | | |
| | Reliability | B | A | B | B | B | B | A |
| | Bonding | A | A | A | A | B | A | A |
| | accuracy | | | | | | | |

| | | Example | Comparative | Comparative | Comparative | Comparative | Comparative |
|---|---|---|---|---|---|---|---|
| | | 15 | Example 1 | Example 2 | Example 3 | Example 4 | Example 5 |
| Formulation of sealant | Component | 60 | 80 | 60 | 80 | 80 | |
| composition (parts by mass) | (A) 1 | | | | | | |
| | Component | | 20 | | | | 100 |
| | (A) 2 | | | | | | |
| | Component | | | | | | |
| | (B) 1 | | | | | | |
| | Component | 3 | | | | | |
| | (B) 2 | | | | | | |
| | Component | | | | | | |
| | (C) 1 | | | | | | |
| | Component | 40 | | 40 | 20 | 20 | |
| | (C) 2 | | | | | | |
| | Component | | | | | | |
| | (D) | | | | | | |
| | Component | | | | | 2 | |
| | (E) | | | | | | |
| | Component | 10 | 10 | 10 | 10 | 10 | 10 |
| | (F) | | | | | | |
| | Component | 1 | | | | | |
| | (G) | | | | | | |
| | Thermosetting | | 3 | | | | 3 |
| | curing agent | | | | | | |
| | Photo cationic | | | 3 | 3 | | |
| | generator | | | | | | |
| Presence or | | Absent | Present | Absent | Absent | Absent | Present |
| absence of | | | | | | | |
| heat treatment | | | | | | | |
| Evaluation | Screen | A | B | A | B | B | C |
| | printability | | | | | | |
| | Reliability | B | B | C | C | C | — |
| | Bonding | A | C | C | C | C | — |
| | accuracy | | | | | | |

As shown in Table 1, sufficiently photocurable and highly reliable sealants were obtained in Examples involving the component (A), the component (B) and the component (C).

### INDUSTRIAL APPLICABILITY

The disclosure can provide a sealant composition for an organic solar cell capable of forming a sealant that exerts sufficient photocurability, is excellent in adhesiveness to a current collecting wire, and has highly reliable sealing performance. The disclosure can provide a sealant for an organic solar cell, which is excellent in adhesiveness to a current collecting wire and has highly reliable sealing performance. The disclosure can provide an electrode for an organic solar cell, which is excellent in the adhesiveness between a sealant and a current collecting wire and is highly reliable. The disclosure can provide an organic solar cell that is excellent in the adhesiveness between a sealant and a current collecting wire and is highly reliable.

### REFERENCE SIGNS LIST

1: Current collecting wiring module
2: Photoelectrode substrate
3: Conductive film
4: Counter electrode substrate
5: Catalyst layer
6: Sealant
7: Electrolyte layer
8: Current collecting wire
9: Sealant for protection
10: Porous semiconductor fine particle layer

1. A sealant composition for an organic solar cell, comprising:
(A) a hydrogenated epoxy resin;
(B) a photobase generator; and
(C) an anionically curable compound other than the component (A).

2. The sealant composition for an organic solar cell according to claim 1, wherein the component (A) is a hydrogenated novolac-type epoxy resin and/or a hydrogenated bisphenol-type epoxy resin.

3. The sealant composition for an organic solar cell according to claim 1, wherein the component (C) comprises a cyclic epoxy resin.

4. The sealant composition for an organic solar cell according to claim 1, wherein the sealant composition comprises 10 to 90 parts by mass of the component (A) per 100 parts by mass in total of the component (A) and the component (C).

5. The sealant composition for an organic solar cell according to claim 1, further comprising (D) an acid anhydride and/or (E) a radical photoinitiator.

6. The sealant composition for an organic solar cell according to claim 1, further comprising (F) a filler.

7. A sealant for an organic solar cell, which is a cured product of a sealant composition for an organic solar cell according to claim 1.

8. A sealant for an organic solar cell prepared by curing a sealant composition for an organic solar cell according to claim 1 by light irradiation, followed by further curing by heating.

9. An electrode for an organic solar cell, comprising:
a substrate;
a current collecting wire on the substrate; and
a sealant covering the current collecting wire, wherein
the current collecting wire is a photocured product, and
the sealant is a photocured product of a sealant composition for an organic solar cell according to claim 1.

10. The electrode for an organic solar cell according to claim 9, wherein the substrate is a flexible substrate.

11. The electrode for an organic solar cell according to claim 9, wherein the electrode for an organic solar cell is a photoelectrode, wherein the photoelectrode comprises a porous semiconductor fine particle layer and
is prepared by photocuring the current collecting wire and the sealant, then coating the substrate with a material for the porous semiconductor fine particle layer, and heating the sealant and the material for the porous semiconductor fine particle layer to form the porous semiconductor fine particle layer.

12. The electrode for an organic solar cell according to claim 11, wherein a temperature of the heating is 150° C. or lower.

13. An organic solar cell prepared by using a sealant composition for an organic solar cell according to claim 1.

14. An organic solar cell comprising an electrode for an organic solar cell according to claim 9.
